(19) United States
(12) Patent Application Publication
(10) Pub. No.: US 2008/0040639 A1
(43) Pub. Date: Feb. 14, 2008

(54) Apparatus and Method For Generating Test Pattern Data For Testing Semiconductor Device

(75) Inventor: Jong Koo KANG, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: Unitest Inc., Yongin-si (KR)

(21) Appl. No.: 11/830,081

(22) Filed: Jul. 30, 2007

(30) Foreign Application Priority Data
Aug. 9, 2006 (KR) 10-2006-0075056

(51) Int. Cl. G01R 31/3177

(52) U.S. Cl. 714/738; 714/E11.002

(57) ABSTRACT

An apparatus and a method for generating a test pattern data for testing a semiconductor device are disclosed. In accordance with and in particular to the apparatus and the method, a test pattern program is compiled by predicting a data operation to generate a test pattern data in an interleaved fashion, thereby eliminating a need for a developer of the test pattern program to analyze the data operation during a writing of a source code.

### BACKGROUND OF THE INVENTION

1. Field of the Invention

The present invention relates to an apparatus and a method for generating a test pattern data for testing a semiconductor device, and in particular to an apparatus and a method for generating a test pattern data for testing a semiconductor device wherein a test pattern program is compiled by predicting a data operation to generate a test pattern data in an interleaved fashion, thereby eliminating a need for a developer of the test pattern program to analyze the data operation during a writing of a source code.

2. Description of Prior Art

A tester for testing a semiconductor device tests whether the semiconductor device is defective. The tester for testing the semiconductor device is designed and developed according to a development state of a memory device, a DRAM in particular which takes up most of the memory devices since the tester for testing the semiconductor device is mostly used for testing the memory devices.

The development of the DRAM is progressing from an EDO (Extended Data Output) DRAM, SDRAM (Synchronous DRAM), Rambus DRAM to DDR (Double Data Rate) DRAM.

In order to test the DRAM, a high speed and a high accuracy are required for the tester so as to correspond to a high speed DRAM. In addition, as a capacity of the memory is increased, a time required for testing the DRAM also increases. Therefore, a testing speed is also required to be increased. Moreover, a cost for testing the memory should be reduced by embodying a miniaturized and economical tester.

Of the tester for testing the semiconductor device, the memory tester in particular is typically used for testing and verifying a memory component or a memory module in a form of a SIMM or DIMM. The tester detects a functional defect of the memory module or the memory component prior to an installation thereof in a real computer system.

The tester is classified into a hardware semiconductor device tester and a software diagnostic program executed in a PC environment. However, since the software diagnostic program diagnoses a state of the memory when the memory module or the memory component is installed in the real computer, the hardware semiconductor device tester is mainly used during a semiconductor memory manufacturing process.

The tester may be classified as a high-end tester referred to as an ATE (Automatic Test Equipment), a medium range memory tester and a low-end memory tester.

The ATE which is the high-end tester is typically used in order to carry out a test process of the memory device. The conventional ATE carries out tests such as a DC test for testing whether a DC parameter is suitable for a digital operation of a circuit, a transmission delay time of signals, and an AC margin related to a set-up time and a hold time. The ATE also generates a test pattern and a timing for the test. However, a manufacturing cost of the ATE is high since the ATE is manufactured using a dedicated equipment such as a main frame having a large size and a high price.

FIG. 1 is a block diagram illustrating a conventional tester for testing a semiconductor device.

As shown in FIG. 1, the conventional tester comprises a pattern generator 110, a timing generator 120, a format controller 130, a driver 140, an output comparator 150, and a test result storage 160. In addition to these components, the conventional tester may comprise a power supply controller for the DC test, a component for generating a clock signal, a component for supplying a power for an operation of a DUT (Device Under Test) 180, a component for relaying a test pattern data to the DUT 180 and receiving a test result from the DUT 180, a component for receiving a test pattern program from an outside, and a component for transmitting the test result to the outside. However, a description thereof is omitted.

The pattern generator 110 generates the test pattern data required for testing the DUT 180 based on the test pattern program. For instance, the test pattern program is written to include an instruction for carrying out various operations in order to carry out the test. The pattern generator 110 generates the test pattern data by receiving and interpreting the test pattern program from an external storage for instance. The test pattern data includes a data such as a command, address and a data inputted to the DUT 180. In addition, an expected data corresponding to the generated test pattern data is generated.

The timing generator 120 generates a timing edge which is a reference for converting the test pattern data generated in the pattern generator 110 into various waveforms. The timing edge is generated using a plurality of clocks for a smooth conversion.

The format controller 130 converts the test pattern data to a desired waveform based on the timing edge.

The driver 140 transmits the converted test waveform to the DUT 180.

The comparator 150 tests the DUT 180 by comparing the test output data being outputted from the DUT 180 after an operation of the DUT 180 is complete by the test waveform applied to the DUT 180 with the expected data generated in the pattern generator 110.

The test result storage 160 stores a test result based on a result of the comparison of the comparator 150. For instance, an information on a defective DUT is stored.

As described above, the conventional ATE is a very highly priced equipment. Therefore, it is preferable that a manufacturer designs the highly priced ATE efficiently in order to increase a competitiveness by minimizing a manufacturing cost thereof. For the efficient design of the ATE, the generation of the test pattern and the timing should be optimized.

Particularly, the test pattern data should correspond to an operation of the semiconductor device in order to carry out the test of the semiconductor device. However, the pattern generator 110 that generates the test pattern data is generally embodied using a programmable logic device such as an FPGA operating at a low speed. Therefore, the pattern generator 110 employs a plurality of algorithm pattern generators in an interleaved fashion to generate the test pattern data suitable for the semiconductor device operating at a high speed.

A pattern generating apparatus employing the plurality of algorithm pattern generators is disclosed in Korean Patent No. 220201 titled “Pattern Generating Circuit” filed on Nov. 26, 1996 and registered on Jun. 19, 1999 by Ando Electric Co., Ltd., and Korean Patent No. 242604 titled “Semiconductor Device Tester” filed on Jan. 14, 1997 and registered on Nov. 14, 1999 by Advantest Corporation.

FIG. 2 is a diagram illustrating a conventional apparatus for generating a test pattern data.

Referring to FIG. 2, the conventional apparatus for generating the test pattern data comprises a sequence controller 210, a plurality of algorithm pattern generators 220a through 220d and a multiplexer 230.

The sequence controller 210 fetches an instruction and transmits an instruction pointer included in the instruction to each of the plurality of algorithm pattern generators 220a through 220d.

Each of the plurality of algorithm pattern generators 220a through 220d carries out a predetermined data operation based on the instruction pointer transmitted from the sequence controller 210 and outputs a result thereof as an output data.

The output data includes a command, an address and a data constituting the test pattern data. The output data may also include an expected data corresponding to the test pattern data. Because each of the plurality of algorithm pattern generators 220a through 220d is embodied using a device operating at the low speed, a component for applying the output data in a proper format to the semiconductor device operating at the high speed is required.

The multiplexer 230 multiplexes, i.e. serializes the output data of each of the plurality of algorithm pattern generators 220a through 220d to generate the test pattern data suitable for the semiconductor device.

That is, the multiplexer 230 synthesizes the output data which is a result of the data operation carried out by the plurality of algorithm pattern generators 220a through 220d in parallel.

For instance, the FPGA embodying each of the plurality of algorithm pattern generators 220a through 220d has an operating speed of about 300 MHz. Therefore, the output data of each of the plurality of algorithm pattern generators 220a through 220d is suitable for the operation speed of 300 MHz. When the output data is multiplexed using the multiplexer 230, the test pattern data of 1.2 GHz may be obtained.

When the test pattern data is not generated in the interleaved fashion, a frame is same a cycle. However, when the test pattern data is generated in the interleaved fashion, i.e. when four algorithm pattern generators are used as one algorithm pattern generator for instance, four cycles constitute one frame. The frame refers to a time period necessary for an entirety of the plurality of algorithm pattern generators 220a through 220d, and the cycle refers to a time period necessary for each of the plurality of algorithm pattern generators 220a through 220d.

Therefore, the plurality of algorithm pattern generators 220a through 220d carry out the predetermined data operation for each of the cycles during the one frame and output the results of the data operation as the test pattern data.

The plurality of algorithm pattern generators 220a through 220d of the conventional tester are embodied using separate hardwares and operate independently. However, even when the separate hardwares are used to embody the plurality of algorithm pattern generators 220a through 220d, an operation efficiency of the algorithm pattern generators 220a through 220d is improved by predicting a result of the data operations within each of the cycles. In addition, the test pattern data may be efficiently generated when the plurality of algorithm pattern generators 220a through 220d embodied using separate hardwares are regarded as one algorithm pattern generator.

Therefore, the algorithm pattern generators 220a through 220d are logically correlated.

A method described below may be used to embody the logical correlation.

The test pattern program is generated such that each of the algorithm pattern generators 220a through 220d independently carries out the data operation for each of the cycles, and the output data of each of the algorithm pattern generators 220a through 220d is then combined to generate the test pattern data.

The method is advantageous in that an embodiment of the correlation is simple and the instruction, i.e. the data operation that may be correlated is not limited because the correlation is calculated by a developer of the test pattern program.

However, the developer of the test pattern program cannot intuitively write the test pattern program and should write the test pattern program by considering an internal operation relation. Therefore, the test pattern program is difficult to write for the developer. That is, the developer of the test pattern program should calculate the data operation of every correlated cycle because the correlation between operation registers of the algorithm pattern generators 220a through 220d. Therefore, the developer of the test pattern program should undergo a complex process to write the test pattern program.

Moreover, a compiler may convert and compile the test pattern program in a manner that the data operation is predicted by the cycle and correlated in the algorithm pattern generators 220a through 220d. In such case, the developer of the test pattern program may regard the algorithm pattern generators 220a through 220d as one algorithm pattern generator when writing the test pattern program.

The complier predicts the data operation that should be carried out by each of the algorithm pattern generators 220a through 220d by the cycle such a previous cycle and a current cycle and then converts and compiles the test pattern program to a new operation code based on a result of the prediction rather than directly compiling the test pattern program written by the developer of the test pattern program. The algorithm pattern generators 220a through 220d carry out the data operation based on the converted test pattern program. When the test pattern program is converted and compiled, the writing of the test pattern program is facilitated for the developer of the test pattern program. However, the embodiment of the algorithm pattern generators 220a through 220d is difficult and the instruction that may be used is limited.

Particularly, when the data operation using a plurality of fields for generating the test pattern program, a number of the instructions suitable for prediction and the conversion is limited. Moreover, because the plurality of fields are used, the number of the instructions limited between an operation code in the cycle of a previous frame and an operation code in the cycle of a current frame is increased.

### SUMMARY OF THE INVENTION

It is an object of the present invention to provide an apparatus and a method for generating a test pattern data for testing a semiconductor device wherein a test pattern program is compiled by predicting a data operation to generate a test pattern data in an interleaved fashion, thereby eliminating a need for a developer of the test pattern program to analyze the data operation during a writing of a source code.

In order to achieve the above-described objects of the present invention, there is provided an apparatus for generating a test pattern data for testing a semiconductor device, the pattern generator comprising: a test pattern program reader for reading a test pattern program generated by predicting a data operation in a manner that the data operation for different frames is allowed irrelevant of a data prediction condition and only the data operation for a plurality of interleaving cycles within a single frame compliant to the data prediction condition is allowed; a plurality of algorithm pattern generators for carrying out the data operation in an interleaved fashion based on the test pattern program to generate a pattern; and a multiplexer for multiplexing the pattern to generate the test pattern data for testing the semiconductor device.

There is also provided a method for generating a test pattern data for testing a semiconductor device, the method comprising steps of: (a) reading a test pattern program generated by predicting a data operation in a manner that the data operation for different frames is allowed irrelevant of a data prediction condition and only the data operation for a plurality of interleaving cycles within a single frame compliant to the data prediction condition is allowed; (b) carrying out the data operation in an interleaved fashion based on the test pattern program to generate a pattern; and (c) multiplexing the pattern to generate the test pattern data for testing the semiconductor device.

### BRIEF DESCRIPTION OF THE DRAWINGS

FIG. 1 is a block diagram illustrating a conventional tester for testing a semiconductor device.

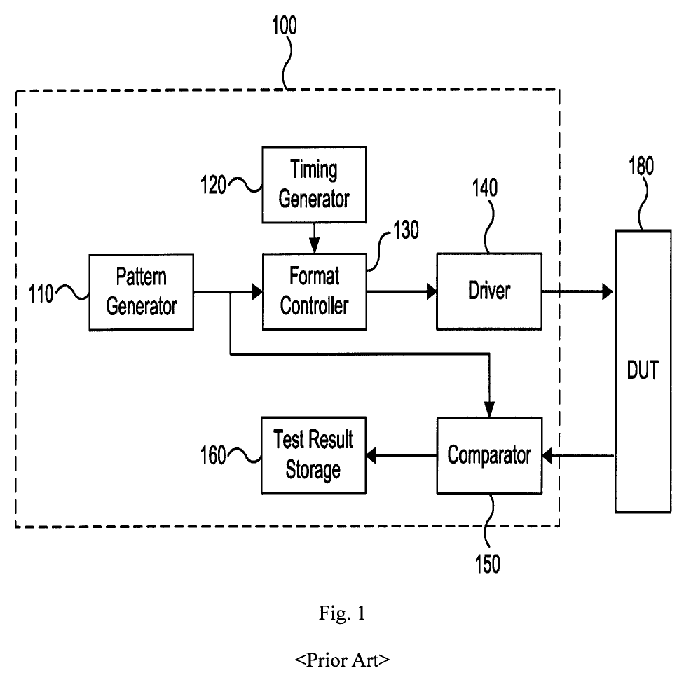

FIG. 2 is a diagram illustrating a conventional apparatus for generating a test pattern data.

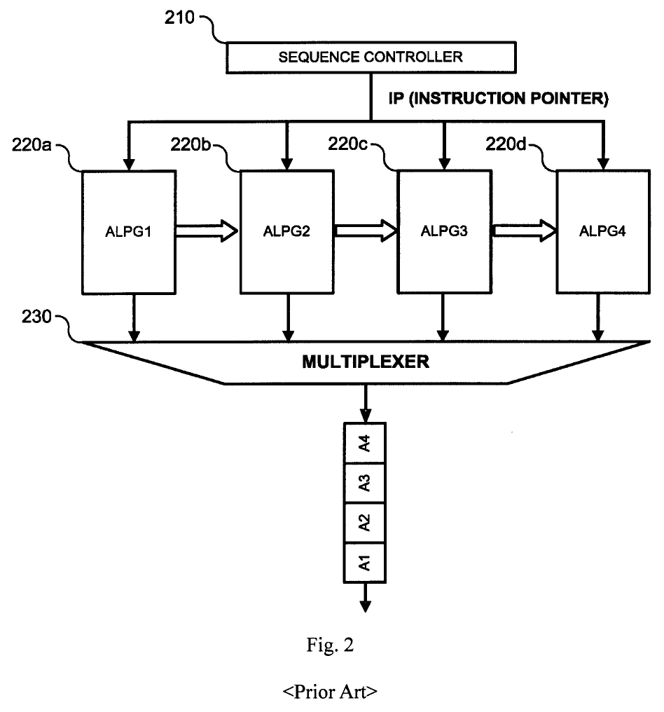

FIG. 3 is a block diagram illustrating an apparatus for generating a test pattern data for testing a semiconductor device in accordance with the present invention.

FIG. 4 is a diagram illustrating an operation for a plurality of fields in an apparatus for generating a test pattern data for testing a semiconductor device in accordance with the present invention.

FIG. 5 is a diagram illustrating a compiling process in an apparatus for generating a test pattern data for testing a semiconductor device in accordance with the present invention.

FIG. 6 is a flow diagram illustrating a method for generating a test pattern data for testing a semiconductor device in accordance with the present invention.

### DETAILED DESCRIPTION OF THE PREFERRED EMBODIMENTS

The present invention will now be described in detail with reference to the accompanied drawings.

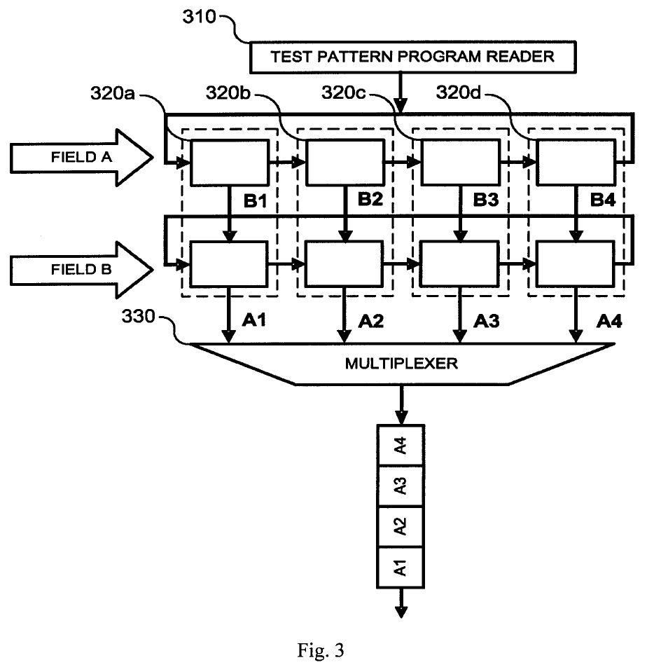

FIG. 3 is a block diagram illustrating an apparatus for generating a test pattern data for testing a semiconductor device in accordance with the present invention.

Referring to FIG. 3, the apparatus in accordance with the present invention comprises a test pattern program reader 310, a plurality of algorithm pattern generators 320a through 320d and a multiplexer 330.

The test pattern program reader reads a test pattern program.

The test pattern program is generated by a test pattern program processor (not shown) connected to the apparatus.

The test pattern program processor is connected to the pattern generator which compiles a source code written by a a developer of the test pattern program to generate the test pattern program.

Preferably, the test pattern program processor is included in a semiconductor device tester comprising the apparatus of the present invention. In addition, the test pattern program processor may be separate device.

In order to generate the test pattern program, the pattern generator comprises a compiler for compiling the source code to generate the test pattern program, and a test pattern program inspector for determining whether the source code includes only the data operation compliant to the data prediction condition.

The complier compiles the source code when the source code is determined to include only the data operation compliant to the data prediction condition.

The compiler generates an executable binary code from the source code. In accordance with the present invention, the source code is converted prior to the compiling based on the data prediction condition if required.

The complier stops compiling the source code when the source code is determined to include the data operation incompliant to the data prediction condition, and outputs an error message such that the developer of the test pattern program configures the source code to include only the data operation compliant to the data prediction condition.

The test pattern program is predicted and complied in a manner that the data operation for different frames is allowed irrelevant of a data prediction condition and only the data operation compliant to the data prediction condition for a plurality of interleaving cycles within a single frame is allowed.

The conventional test pattern program predicts the data operation for the different frames as well as a single frame to embody an interleaving. Because the test pattern program embodies the interleaving based on a data prediction for a data operation code corresponding to a last interleaving cycle of a previous frame and a data operation code corresponding to a first interleaving cycle of a current frame, an instruction that may be used in connection with the different frames, i.e. the data operation is limited in the conventional test pattern program.

Contrary to the conventional test pattern program, the test pattern program used in the apparatus in accordance with the present invention is complied by predicting the data operation in a manner that the data operation for the different frames is allowed irrelevant of the data prediction condition and only the data operation for the plurality of interleaving cycles within the single frame compliant to the data prediction condition is allowed. Therefore, the limitation in the data operation exist only in each interleaving cycle in the single frame in accordance with the present invention. As a result, the limitation of the data operation in carrying out the interleaving through the prediction of the data operation is reduced.

The test pattern program reader 310 may read the test pattern program in order to generate the test pattern data after storing the test pattern program in an instruction memory.

The reading process may include fetching the instruction or a data from the test pattern program for generating the test pattern data through a sequence control.

The algorithm pattern generators 320a through 320d generates a pattern after carrying out the data operation in an interleaved fashion based on the test pattern program. While four algorithm pattern generators are shown, two or three algorithm pattern generators may be used. However, two or four algorithm pattern generators may be used for an efficient interleaving.

The data operation in the interleaved fashion is carried out based on each of the frames in the test pattern program. Each of the frames includes interleaving cycles corresponding to a number of the algorithm pattern generators 320a through 320d, and each of the algorithm pattern generators 320a through 320d carries out the data operation corresponding to the interleaving cycle thereof in parallel. While the algorithm pattern generators 320a through 320d are embodied using separate hardwares, the interleaving may be embodied such that the algorithm pattern generators 320a through 320d are logically correlated.

A result of the data operation corresponding to the last interleaving cycle is fed back to the data operation corresponding to the first interleaving cycle. Through the feedback, the frames may be correlated. The apparatus in accordance with the present invention is not limited in predicting the data operation between the frames through the correlation by the feedback. That is, while the data operation may be limited between the frames in the interleaving fashion through the prediction in accordance with the conventional technology, the limitation of the data operation may be overcome by the feedback in accordance with the present invention.

Each of the algorithm pattern generators 320a through 320d may carry out the data operation for a plurality of fields (a first field and a second field for instance denoted as field A and B in FIG. 3, respectively). The result of the data operation for the field B may affect the data operation for the field A.

Each of the algorithm pattern generators 320a through 320d may include a plurality of operation register. The data operation of each of the interleaving cycles in the single frame is carried out in the plurality of operation registers for the plurality of fields in parallel.

When compiling the test pattern program, the data operation for each of the field A and the field B are predicted and complied for every interleaving cycle in the single frame.

However, the data operation for the field A referring to field B is carried out as described below.

In order to refer to the result of the data operation for the field B, the result of the data operation for the field B in the previous frame is referred to by the data operation for the field A in the current frame. By referring to the result of the data operation in the previous frame, the data operation may be carried out by predicting the data operation compliant to the data prediction condition in each of the interleaving cycles of the current frame.

In addition, the test pattern program is complied to refer to the previous frame for the data operation referring to different fields. That is, the algorithm pattern generator 320a carries out the data operation for the field B to output a value B1, and the value B1 is referred to by the data operation of field A in a next frame to output a value A1. The outputs A1 through A4 of The algorithm pattern generators 320a through 320d is then multiplexed to be outputted as the test pattern data.

By referring to the result of the data operation for the second field in the previous frame instead of the current frame even in case of referring to a data of the second field as well as the data operation for the first field, the data operation may be predicted to embody the correlation within the same frame. The embodiment of the correlation within the same frame reduces the limitation of the instruction applicable to the current frame, i.e. the data operation.

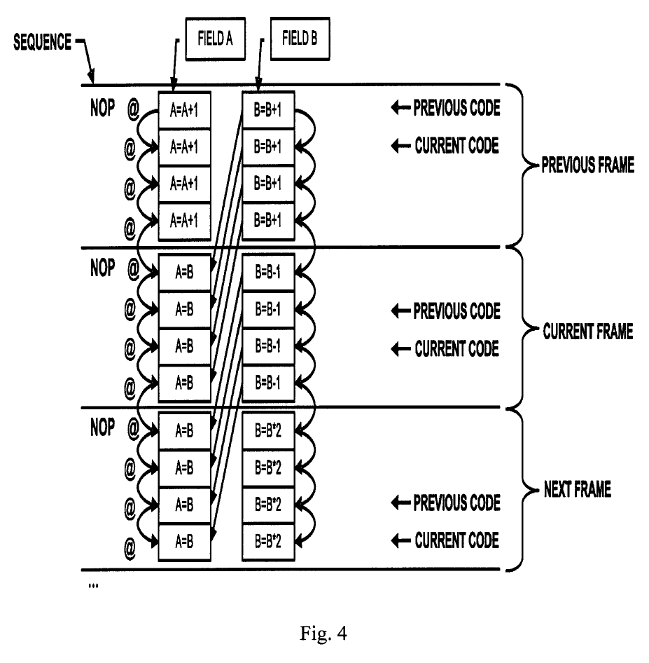

FIG. 4 is a diagram illustrating an operation for the plurality of fields in the apparatus for generating the test pattern data for testing the semiconductor device in accordance with the present invention.

FIG. 4 depicts each sequence of the test pattern program read by the test pattern program reader and the data operation code for the plurality of algorithm pattern generators (four algorithm pattern generators for instance) corresponding to each sequence. In addition, FIG. 4 depicts the previous frame, the current frame and the next frame for each sequence.

An arrow in FIG. 4 represents the correlation.

A description of the first frame (denoted as the previous frame) is as follows.

When the source code is written such that each of the four algorithm pattern generators carries out the data operation of ‘A=A+1’ for the field A and the data operation of ‘B=B+1’ for the field B, the result of the data operation of ‘A=A+1’ or the data operation of ‘B=B+1’ affects a next interleaving cycle, i.e. a next data operation of the algorithm pattern generator.

A description of the second frame (denoted as the current frame) is as follows.

When the source code is written such that each of the four algorithm pattern generators carries out the data operation of ‘A=B’ for the field A and the data operation of ‘B=B−1’ for the field B, the result of the data operation of ‘A=B’ affects the data operation of the next data operation. In addition, because the data operation for the field B does not refer to the result of the data operation for other field, each of the interleaving cycles may be configured in a manner that the data operation is allowed through the prediction within the previous frame.

A description of the third frame (denoted as the next frame) is as follows.

When the source code is written such that each of the four algorithm pattern generators carries out the data operation of ‘A=B’ for the field A and the data operation of ‘B=B*2’ for the field B, the result of the data operation of ‘A=B’ affects the data operation of the next data operation. Therefore, the data operation for the field A in the next frame is carried out by referring to the result of the data operation for the field B in the current frame. In addition, because the data operation for the field B does not refer to the result of the data operation for other field, each of the interleaving cycles may be configured in a manner that the data operation is allowed through the prediction within the current frame.

Referring back to FIG. 3, the multiplexer 330 multiplexes the pattern to generate the test pattern data for testing the semiconductor device.

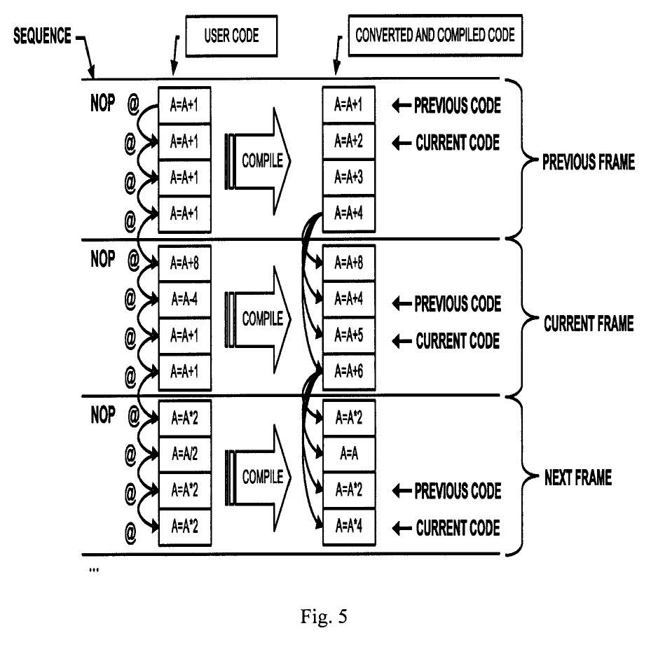

FIG. 5 is a diagram illustrating a compiling process in the apparatus for generating a test pattern data for testing a semiconductor device in accordance with the present invention.

FIG. 5 depicts each sequence of the test pattern program read by the test pattern program reader, the source code (denoted as “user code”) for the plurality of algorithm pattern generators (first through fourth algorithm pattern generators for instance) corresponding to each sequence and the converted and compiled code by predicting the source code to be correlated. FIG. 5 also depicts the previous frame, the current frame and the next frame for the source code and the converted and compiled code in each sequence.

In accordance with the source code, the first algorithm pattern generator carries out a data operation “A=A+1” in the previous frame, and the second algorithm pattern generator carries out the data operation “A=A+1” by receiving the result of the data operation of the first algorithm pattern generator. Since the source code is written assuming that the plurality of algorithm pattern generators are correlated although not, the source code should be converted.

That is, the source code is converted and compiled by the compiler such that the first algorithm pattern generator carries out the data operation “A=A+1”, and the second algorithm pattern generator carries out the data operation “A=A+2” by logically considering the result of the data operation of the first algorithm pattern generator. Similarly, the source code is converted and compiled such that the third algorithm pattern generator carries out a data operation “A=A+3”, and the fourth algorithm pattern generator carries out a data operation “A=A+4”. The data operation corresponding to the converted and compiled code is then carried out by the plurality of algorithm pattern generators.

The data operation for the current frame is carried out based on a result of a last data operation in the previous frame.

That is, the source code is converted and compiled by the compiler such that the first algorithm pattern generator carries out the data operation “A=A+8”, and the second algorithm pattern generator carries out the data operation “A=A+4” instead of “A=A−4” by logically considering the result of the data operation of the first algorithm pattern generator. Similarly, the source code is converted and compiled such that the third algorithm pattern generator carries out a data operation “A=A+5” instead of “A=A+1” and the fourth algorithm pattern generator carries out a data operation “A=A+6” instead of “A=A+1”. The data operation corresponding to the converted and compiled code is then carried out by the plurality of algorithm pattern generators.

The data operation for the next frame is carried out based on a result of a last data operation in the current frame.

That is, the source code is converted and compiled by the compiler such that the first algorithm pattern generator carries out the data operation “A=A*2”, and the second algorithm pattern generator carries out the data operation “A=A” instead of “A=A/2” by logically considering the result of the data operation of the first algorithm pattern generator. Similarly, the source code is converted and compiled such that the third algorithm pattern generator carries out a data operation “A=A*2” by logically considering the result of the data operation of the second algorithm pattern generator and the fourth algorithm pattern generator carries out a data operation “A=A*4” instead of “A=A*2”. The data operation corresponding to the converted and compiled code is then carried out by the plurality of algorithm pattern generators.

The compiler may convert and compile the source code by considering the correlation between the previous code and the current code within the same frame. However, the conversion is not applied to all data operations.

Table 1 shows a combination of the previous code and the predictable current code and the predicted data operation, i.e. the predetermined data prediction condition.

TABLE 1

| | | PREVIOUS CODE | | | | | | |
|---|---|---|---|---|---|---|---|---|
| | | A = A | A = /A | A = A * 2 | A = A/2 | A = B | A = A + B | A = A − B |
| CURRENT | A = A | A = A | A = /A | A = C | A = C | A = B | A = A + B | A = A − B |
| CODE | A = /A | A = /A | A = A | X | X | X | X | X |
| | A = A * 2 | A = C * 2 | X | A = C * 2 | A = C | X | X | X |
| | A = A/2 | A = C/2 | X | A = C | A = C/2 | X | X | X |
| | A = B | A = B | A = B | A = B | A = B | A = B | A = B | A = B |
| | A = A + B | A = A + B | X | X | X | X | X | X |
| | A = A − B | A = A − B | X | X | X | X | X | X |
| | A = A&B | A = A&B | X | X | X | X | X | X |
| | A = A\|B | A = A\|B | X | X | X | X | X | X |
| | A = A\hat{ }B | A = A\hat{ }B | X | X | X | X | X | X |
| | A = imm | A = imm | A = imm | A = imm | A = imm | A = imm | A = imm | A = imm |
| | A = A + imm | A = C + imm | X | X | X | X | X | X |
| | A = A − imm | A = C − imm | X | X | X | X | X | X |

| | | PREVIOUS CODE | | | | | |
|---|---|---|---|---|---|---|---|
| | | A = A&B | A = A\|B | A = A\hat{ }B | A = imm | A = A + imm | A = A − imm |
| CURRENT | A = A | A = A&B | A = A\|B | A = A\hat{ }B | A = imm | A = C | A = C |
| CODE | A = /A | X | X | X | X | X | X |
| | A = A * 2 | X | X | X | X | X | X |
| | A = A/2 | X | X | X | X | X | X |
| | A = B | A = B | A = B | A = B | A = B | A = B | A = B |
| | A = A + B | X | X | X | X | X | X |
| | A = A − B | X | X | X | X | X | X |
| | A = A&B | X | X | X | X | X | X |
| | A = A\|B | X | X | X | X | X | X |
| | A = A\hat{ }B | X | X | X | X | X | X |
| | A = imm | A = imm | A = imm | A = imm | A = imm | A = imm | A = imm |
| | A = A + imm | X | X | X | X | A = C + imm | A = C + imm |
| | A = A − imm | X | X | X | X | A = C − imm | A = C − imm |

‘A’ and ‘B’ represents the data field, ‘C’ represents a previously complied code, ‘X’ represents an unpredictable code, ‘imm’ represents an immediate value, ‘/’ represents a division operator, ‘*’ represents a multiplication operator, ‘+’ represents an addition operator, ‘−’ represents a subtraction operator, ‘&’ represents a bitwise AND operator, ‘|’ represents a bitwise OR operator, and ‘̂’ represents a bitwise XOR operator.

As shown in table 1, the current code may be converted based on the previous code to carry out the data operation.

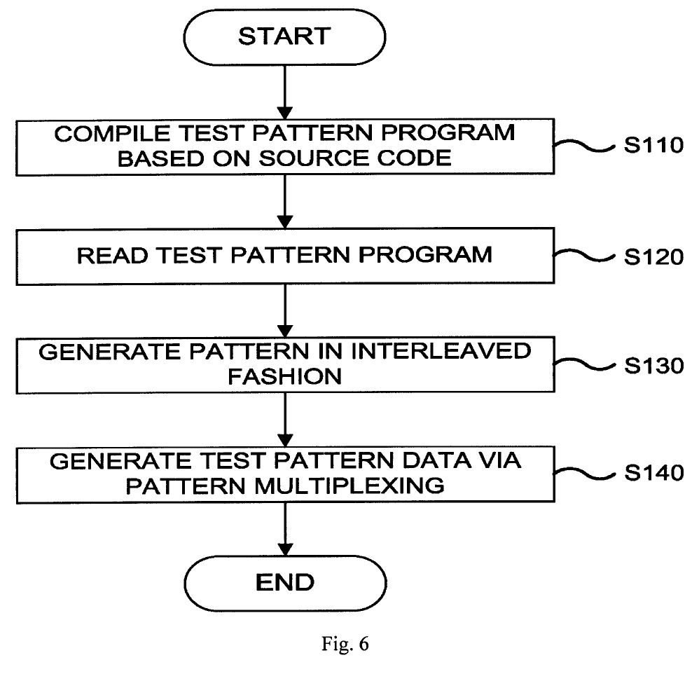

FIG. 6 is a flow diagram illustrating a method for generating the test pattern data for testing the semiconductor device in accordance with the present invention.

Referring to FIG. 6, the source code written by the developer of the test pattern program is compiled to generate the test pattern program (S110).

The test pattern program is complied in a manner that the data operation for different frames is allowed irrelevant of the data prediction condition and only the data operation compliant to the data prediction condition for a plurality of interleaving cycles within the single frame is allowed. The detailed description of the compiling process is given with reference to FIG. 5.

The method in accordance with the present invention may comprise inspecting the source code to determine whether the source code includes only the data operation compliant to the data prediction condition.

When the source code is determined to include the data operation incompliant to the data prediction condition, the compiling is stopped and an error message is outputted.

When the source code is determined to include only the data operation compliant to the data prediction condition, the source code is converted and compiled.

Thereafter, when the test pattern program is generated and stored in the tester, the test pattern program is read and executed (S120).

Thereafter, the data operation is carried out in the interleaved fashion to generate a pattern (S130).

When the data operation is carried out in the interleaved fashion, two or four pattern generations are logically connected, and the pattern is generated by carrying out the data operation to correspond to the interleaving cycle of each of the frames of the test pattern program. The result of the data operation corresponding to the last interleaving cycle is fed back to the data operation corresponding to the first interleaving cycle so that the data operation is not limited in embodying the correlation through the prediction.

In case of the data operation including the plurality of fields, the data operation may be carried out for each of the plurality of fields.

When the data operation may be carried out for each of the plurality of fields, the source code is complied by predicting the data operation referring to the result of the data operation of other field in the previous frame such that the data operation corresponding to each interleaving cycle of the current frame is compliant to the data prediction condition.

Thereafter, the pattern is multiplexed to generate the test pattern data (S140).

The test pattern data is then transmitted to the semiconductor device to be tested.

While the present invention has been particularly shown and described with reference to the preferred embodiment thereof, it will be understood by those skilled in the art that various changes in form and details may be effected therein without departing from the spirit and scope of the invention.

As described above, in accordance with the apparatus and the method for generating the test pattern data for testing the semiconductor device, the test pattern program is compiled by predicting the data operation to generate the test pattern data in the interleaved fashion, thereby eliminating the need for the developer of the test pattern program to analyze the data operation during the writing of the source code.

1. An apparatus for generating a test pattern data for testing a semiconductor device, the apparatus comprising:
a test pattern program reader for reading a test pattern program generated by predicting a data operation in a manner that the data operation for different frames is allowed irrelevant of a data prediction condition and only the data operation for a plurality of interleaving cycles within a single frame compliant to the data prediction condition is allowed;
a plurality of algorithm pattern generators for carrying out the data operation in an interleaved fashion based on the test pattern program to generate a pattern; and
a multiplexer for multiplexing the pattern to generate the test pattern data for testing the semiconductor device.

2. The apparatus in accordance with claim 1, wherein the plurality of algorithm pattern generators are logically connected to one another to carry out the data operation corresponding to the interleaving cycle corresponding to each of the frames, and
wherein a result of the data operation corresponding to a last interleaving cycle is fed back to the data operation corresponding to a first interleaving cycle.

3. The apparatus in accordance with claim 1, wherein each of the plurality of algorithm pattern generators carries out the data operation for first and second fields.

4. The apparatus in accordance with claim 3, wherein the test pattern program is generated by predicting the data operation in a manner that the data operation of the first field corresponding to each of the plurality of interleaving cycles of a current frame is compliant to the data prediction condition by referring to a result of the data operation of the second field of a previous frame.

5. The apparatus in accordance with claim 1, wherein the pattern generator is connected to a test pattern program processor comprising a compiler for compiling a source code to generate the test pattern program, and a test pattern program inspector for determining whether the source code includes only the data operation compliant to the data prediction condition.

6. The apparatus in accordance with claim 5, wherein the complier stops compiling the source code when the source code is determined to include the data operation incompliant to the data prediction condition.

7. The apparatus in accordance with claim 5, wherein the compiler converts the source code based on the data prediction code for each of the plurality of interleaving cycles to generate the test pattern program.

8. The apparatus in accordance with claim 1, wherein the data operation compliant to the data prediction condition is defined by a table

| | PREVIOUS CODE | | | | | | | |
|---|---|---|---|---|---|---|---|---|
| | | A = A | A = /A | A = A * 2 | A = A/2 | A = B | A = A + B | A = A − B |
| CURRENT | A = A | A = A | A = /A | A = C | A = C | A = B | A = A + B | A = A − B |
| CODE | A = /A | A = /A | A = A | X | X | X | X | X |
| | A = A * 2 | A = C * 2 | X | A = C * 2 | A = C | X | X | X |
| | A = A/2 | A = C/2 | X | A = C | A = C/2 | X | X | X |
| | A = B | A = B | A = B | A = B | A = B | A = B | A = B | A = B |
| | A = A + B | A = A + B | X | X | X | X | X | X |
| | A = A − B | A = A − B | X | X | X | X | X | X |
| | A = A&B | A = A&B | X | X | X | X | X | X |
| | A = A\|B | A = A\|B | X | X | X | X | X | X |
| | A = A\hat{ }B | A = A\hat{ }B | X | X | X | X | X | X |
| | A = imm | A = imm | A = imm | A = imm | A = imm | A = imm | A = imm | A = imm |
| | A = A + imm | A = C + imm | X | X | X | X | X | X |
| | A = A − imm | A = C − imm | X | X | X | X | X | X |
| | | PREVIOUS CODE | | | | | |
|---|---|---|---|---|---|---|---|
| | | A = A&B | A = A\|B | A = A\hat{ }B | A = imm | A = A + imm | A = A − imm |
| CURRENT | A = A | A = A&B | A = A\|B | A = A\hat{ }B | A = imm | A = C | A = C |
| CODE | A = /A | X | X | X | X | X | X |
| | A = A * 2 | X | X | X | X | X | X |
| | A = A/2 | X | X | X | X | X | X |
| | A = B | A = B | A = B | A = B | A = B | A = B | A = B |
| | A = A + B | X | X | X | X | X | X |
| | A = A − B | X | X | X | X | X | X |
| | A = A&B | X | X | X | X | X | X |
| | A = A\|B | X | X | X | X | X | X |
| | A = A\hat{ }B | X | X | X | X | X | X |
| | A = imm | A = imm | A = imm | A = imm | A = imm | A = imm | A = imm |
| | A = A + imm | X | X | X | X | A = C + imm | A = C + imm |
| | A = A − imm | X | X | X | X | A = C − imm | A = C − imm, |

where ‘A’ and ‘B’ represents a data field, ‘C’ represents a previously complied code, ‘X’ represents an unpredictable code, ‘imm’ represents an immediate value, ‘/’ represents a division operator, ‘*’ represents a multiplication operator, ‘+’ represents an addition operator, ‘−’ represents a subtraction operator, ‘&’ represents a bitwise AND operator, ‘|’ represents a bitwise OR operator, and ‘̂’ represents a bitwise XOR operator.

9. The apparatus in accordance with claim 1, wherein the plurality of algorithm pattern generators comprises two or four algorithm pattern generators.

10. A method for generating a test pattern data for testing a semiconductor device, the method comprising steps of:
(a) reading a test pattern program generated by predicting a data operation in a manner that the data operation for different frames is allowed irrelevant of a data prediction condition and only the data operation for a plurality of interleaving cycles within a single frame compliant to the data prediction condition is allowed;
(b) carrying out the data operation in an interleaved fashion based on the test pattern program to generate a pattern; and
(c) multiplexing the pattern to generate the test pattern data for testing the semiconductor device.

11. The method in accordance with claim 10, wherein the step (b) comprises (b-1) carrying out the data operation corresponding to the interleaving cycle corresponding to each of the frames by logically connecting a plurality of pattern generation steps to one another, and
wherein a result of the data operation corresponding to a last interleaving cycle is fed back to the data operation corresponding to a first interleaving cycle.

12. The method in accordance with claim 10, wherein the step (b) comprises (b-2) carrying out the data operation for first and second fields.

13. The method in accordance with claim 10, wherein the test pattern program is generated by predicting the data operation in a manner that the data operation of the first field corresponding to each of the plurality of interleaving cycles of a current frame is compliant to the data prediction condition by referring to a result of the data operation of the second field of a previous frame.

14. The method in accordance with claim 10, further comprising, prior to carrying out the step (a):
(d) determining whether a source code includes only the data operation compliant to the data prediction condition by reading the source code; and
(e) compiling a source code to generate the test pattern program when the source code is determined to only include the data operation compliant to the data prediction condition in the step (d).

15. The method in accordance with claim 14, further comprising stopping the compiling of the source code when the source code is determined to include the data operation incompliant to the data prediction condition in the step (d).

16. The method in accordance with claim 15, wherein the step (e) comprises converting and compiling the source code based on the data prediction code for each of the plurality of interleaving cycles to generate the test pattern program.

17. The method in accordance with claim 10, wherein the data operation compliant to the data prediction condition is defined by a table

| | | PREVIOUS CODE | | | | | | |
|---|---|---|---|---|---|---|---|---|
| | | A = A | A = /A | A = A * 2 | A = A/2 | A = B | A = A + B | A = A − B |
| CURRENT | A = A | A = A | A = /A | A = C | A = C | A = B | A = A + B | A = A − B |
| CODE | A = /A | A = /A | A = A | X | X | X | X | X |
| | A = A * 2 | A = C * 2 | X | A = C * 2 | A = C | X | X | X |
| | A = A/2 | A = C/2 | X | A = C | A = C/2 | X | X | X |
| | A = B | A = B | A = B | A = B | A = B | A = B | A = B | A = B |
| | A = A + B | A = A + B | X | X | X | X | X | X |
| | A = A − B | A = A − B | X | X | X | X | X | X |
| | A = A&B | A = A&B | X | X | X | X | X | X |
| | A = A\|B | A = A\|B | X | X | X | X | X | X |
| | A = A\hat{ }B | A = A\hat{ }B | X | X | X | X | X | X |
| | A = imm | A = imm | A = imm | A = imm | A = imm | A = imm | A = imm | A = imm |
| | A = A + imm | A = C + imm | X | X | X | X | X | X |
| | A = A − imm | A = C − imm | X | X | X | X | X | X |
| | | PREVIOUS CODE | | | | | |
|---|---|---|---|---|---|---|---|
| | | A = A&B | A = A\|B | A = A\hat{ }B | A = imm | A = A + imm | A = A − imm |
| CURRENT | A = A | A = A&B | A = A\|B | A = A\hat{ }B | A = imm | A = C | A = C |
| CODE | A = /A | X | X | X | X | X | X |
| | A = A * 2 | X | X | X | X | X | X |
| | A = A/2 | X | X | X | X | X | X |
| | A = B | A = B | A = B | A = B | A = B | A = B | A = B |
| | A = A + B | X | X | X | X | X | X |
| | A = A − B | X | X | X | X | X | X |
| | A = A&B | X | X | X | X | X | X |
| | A = A\|B | X | X | X | X | X | X |
| | A = A\hat{ }B | X | X | X | X | X | X |
| | A = imm | A = imm | A = imm | A = imm | A = imm | A = imm | A = imm |
| | A = A + imm | X | X | X | X | A = C + imm | A = C + imm |
| | A = A − imm | X | X | X | X | A = C − imm | A = C − imm, |

where ‘A’ and ‘B’ represents a data field, ‘C’ represents a previously complied code, ‘X’ represents an unpredictable code, ‘imm’ represents an immediate value, ‘/’ represents a division operator, ‘*’ represents a multiplication operator, ‘+’ represents an addition operator, ‘−’ represents a subtraction operator, ‘&’ represents a bitwise AND operator, ‘|’ represents a bitwise OR operator, and ‘̂’ represents a bitwise XOR operator.

18. The method in accordance with claim 10, wherein the pattern is generated by connecting two or four pattern generations in the interleaved fashion.
